(19) United States
(12) Patent Application Publication
(10) Pub. No.: US 2003/0052728 A1
(43) Pub. Date: Mar. 20, 2003

(54) Digitally-controlled bypassing and real time adjustable analog presets for guitar electronic effect devices and method

(76) Inventor: Justin M. Philpott, Flanders, NJ (US)

Correspondence Address: Justin M. Philpott, 8 Schoolhouse Lane, Flanders, NJ, 07836, US

(21) Appl. No.: 09/954,398

(22) Filed: Sep. 17, 2001

(51) Int. Cl. H03K 17/16

(52) U.S. Cl. 327/385

(57) ABSTRACT

An apparatus and method for providing an analog preset switching system for guitar electronic effect devices is disclosed. The system comprises real-time settable analog presets with LED indication of the preset selection, real-time settable control means for determining how many of the presets are enabled, and true bypass switching means with LED indication of bypass status for switching between effected and non-effected audio signals. A digitally-controlled bypass signal as well as one or more digitally-controlled preset control signals are provided to control analog multiplexers for the real-time settable analog presets and the true bypass switching means. Multiplexing means are also provided for LED indication of the preset selection and bypass status.

### FIELD OF THE PRESENT INVENTION

The present invention relates to the field of switching, including mechanical and electrical configurations. More particularly, the present invention relates to guitar electronic effect devices, and ways for providing bypass switching and presets for such devices.

### BACKGROUND OF THE INVENTION

In the following text, a brief history guitar electronic effect devices is provided, dating as far back as the 1960's with some of the first commercially available guitar electronic effect device which utilized conventional analog mechanical switching methods. Later, in the late 1970's and the 1980's, electronic switching circuits gained widespread use in such effect devices as a way to provide inexpensive, mass-produced products. With the continued advancement of electronics in the mid-1980's, namely the increasing availability of digital integrated circuits and the development of surface mount technology (SMT), the guitar electronic effect device industry began to adapt products to include features such as multiple presets and digital switching. With this digital and SMT advancement the guitar electronic effect device industry became to comprise primarily only a few large companies that provided products with multiple effect devices housed in a single enclosure and controlled by digital electronics. Despite what were considered technological advancements, many guitar players found such digitally-controlled “multi-effects” products less desirable for a variety of reasons that will be discussed herein. Thus, the 1990's brought the resurgence of the “vintage-style”, completely analog electronic effect devices of old. Many new manufacturers quickly became part of the industry by marketing products that were purely analog, mostly hand-made, and with higher quality analog components than their compact multi-effects digital counterparts. At the beginning of the 21^{st} century, the guitar electronic effect device industry appears to be one of division. Vintage-style effect devices are still in great demand by many guitarists. Other guitarists have either remained loyal to the continually developing digital multi-effect devices or have recently accepted newer and improved models of such digitally-controlled devices. However, there exists an increasing number of guitarists in another category who seek a product that bears the sound quality and simplicity of vintage-style, pure analog devices but that also has the added flexibility offered by digital control circuitry.

Basic Elements of Guitar Electronic Effect Devices

An electric guitar player, as well as many acoustic guitar players, requires the most basic equipment of a guitar and an amplifier in order to provide amplified music. However, considered almost as essential to the modern guitarist as a guitar and an amplifier are guitar electronic effect devices. Such effect devices typically include some form of overdrive or distortion device as well as a great variety of other devices such as a tremolo, chorus, phaser, flanger, delay, octavia, pitch shifter, equalizer, compressor, wah, envelope-controlled filter follower, and a growing number of other sound altering devices. These electronic effect devices are connected between the signal path of the guitar (input) and the amplifier (output) and are commonly referred to collectively as an effects chain, wherein more than one effect device may be included in the chain.

Typically, an effect device includes an input and output jack, a bypass switch, an effect device circuit with circuit input and circuit output connections, and control means in the form of knobs for adjusting various features of the device. Additionally, many effect devices comprise LED's (light emitting diodes) that indicate the bypass status of the device, a very useful feature particularly when a plurality of effect devices are connected together in an effects chain. When the bypass switch is engaged in the “on” position, the output of the device is that of a “wet” signal, wherein the effect device has altered the sound of the input, or “dry”, signal. Inversely, when the bypass switch is engaged in the “off” position, the output of the device is that of, or approximately that of, the “dry” guitar signal. The reason for the output signal of a bypassed device not always being precisely equivalent to the input signal can be found in analyzing the bypassing, or the switching, configuration. In the following, various switching configurations and the benefits and the limitations thereof are discussed.

Bypass Switching Configurations

The earliest guitar electronic effect devices to be mounted in foot pedal enclosures (referred to herein as “pedals”) utilized mechanical bypass configurations comprising a hard on-off switch. Some pedals utilized a toggle switch for this operation, but the commonplace quickly became the foot push-button switch, or “stomp switch”.

The stomp switch is a mechanical step-on, step-off style switch wherein contacts are made to opposite nodes with each step of the switch. The first commonly used stomp switch was a single-pole-single-throw (SPDT) type. This switch comprised three poles. The middle pole electrically connected to the output jack of the effect device and the top and bottom poles electrically connected to the input jack and the circuit output, respectively. The device input jack was additionally electrically connected to the circuit input. In operation, the output jack electrically connected to either the circuit output, yielding a “wet” signal, or the input jack which yielded an approximately “dry” signal. One clear downside to this configuration, however, was that the jack input was always connected to the circuit input. As a result, in bypass mode the jack output signal was not equivalent to the jack input signal as would be the case if the effect device were truly bypassed. Rather, in the case of the bypass mode in SPDT switching, part of the input signal was lost due to its being coupled to the circuit input as well. This loss of signal was highly undesirably and was particularly noticed by many discerning guitarists. A further limitation to this SPDT switching configuration is that LED indication of the bypass status was not provided.

In a way to meet the demands for a pedal that comprised LED indication of the bypass status, some effect device manufacturers began to use double-pole-double-throw (DPDT) stomp switches in their products. A DPDT switch offered the equivalent of two SPDT switches in a single stomp switch. Thus, with one side (i.e., the first set of three poles) of the DPDT the manufacturer wired the switch just like the SPDT. On the other side of the switch (i.e., the second set of three poles) the manufacturer electrically connected the middle pole to the circuit ground and the bottom pole to the cathode of an LED, with the anode of the LED electrically connected to the device's positive voltage terminal. A resistor typically was added at one of the ends of the LED to protect the LED from damage due to high current. Variations of this arrangement also existed, but with the same common elements.

While the DPDT with LED configuration allowed for the indication of bypass status, the device still suffered from loss of signal in bypass mode as in the previous SPDT configuration. However, some manufacturers chose to use the DPDT stomp switch not to solve the LED indication of bypass status dilemma, but to provide a better switching configuration that came to be referred to as “True Bypass”. Instead of wiring the DPDT like that of the SPDT switch, True Bypass allowed for the connection of each element to a separate pole. For example, the jack input and jack output were electrically connected to the two middle poles, left and right, respectively. The circuit input and circuit outputs were electrically connected to the two top poles, left and right, respectively. Then, the two bottom poles were electrically connected to each other. In such a configuration, in “off” or bypass mode the jack input electrically connected only to the jack output by means of the two electrically connected bottom poles, and in “on” mode the jack input electrically connected directly to the circuit input while the jack output electrically connected directly to the circuit output. While a straightforward wiring configuration, one initial limitation of this style of DPDT True Bypass switching is that due to the mechanical nature of the switch, a pop sound may frequently occur during switching. This particular pop sound may be attributed to the configuration surrounding the circuit input connection wherein, upon engaging the bypass switch, the circuit input is left “hanging” after being previously electrically connected to the input jack and thus, input signal. That is, noise results as the signal located at the circuit input dissipates upon engaging the switch to bypass mode. Nevertheless, this True Bypass wiring with a DPDT stomp switch does solve the loss of signal problem in bypass mode previously discussed, making it much more suitable for studio use where signal loss, or decreased signal quality, cannot be tolerated. Despite the improvement in switching performance regarding signal loss, however, the user is left without LED indication of bypass status in the True Bypass DPDT configuration. Therefore, the effect device manufacturer had to chose one feature over the other. In each case, their product was limited, either in lack of LED status or through the loss of signal in bypass mode.

In the midst of the True Bypass/LED indication dilemma was another switching alternative quickly gaining widespread use, in particular in the lower-priced devices. What will be referred to as FET (field effect transistor) switching, this alternative switching configuration used the advancement of FET and electronic switching technology to provide a very inexpensive switching method that also provided LED indication of bypass status. The FET switching arrangement only required a momentary single-pole-single-throw (SPST) switch. Such switches were typically more than five times less expensive than their SPDT and DPDT stomp switch counterparts. Furthermore, the FET switching arrangement allowed for LED indication, reducing even more the desirability of the original SPDT stomp switch. By using much more cost-effective electronic components in place of a bulky, heavy stomp switch, these FET-comprising effect devices quickly became more commonplace than stomp switch configured devices in the 1980's.

Nevertheless, the FET switching arrangement comprised more than a fair share of limitations. When compared even to the SPDT configuration, the FET switching configuration typically resulted in even greater loss of signal in bypass mode due to the non-mechanical nature of the switching and additional circuit components which result in input signal dissipation. Furthermore, many devices comprising FET switching were prone to loud electrical pops or squeaks occurring upon each engagement of the foot switch, something highly undesirable when using the devices in live performances. Finally, the FET switching configurations by nature required a power supply to function. While it did not initially appear to be a problem given that nearly all effect devices already required a power supply to operate, difficulties quickly arose when a power supply, which was very commonly in the form of a battery source, was exhausted. In previous mechanical switching configurations, i.e. with SPDT and DPDT stomp switches, the user was always able to bypass the device. In the event that the power supply became exhausted, the user could simply switch the device off and continue performing with a dry signal. However, in the case of FET switching, if the power supply is exhausted, the user was left unable to switch to the bypass mode. Thus, the user was left with no signal at the device's output and at that point must have had to have either changed the power supply or manually disconnected the device from the effects chain, an unacceptable requirement for live performances. Despite these drastic limitations of the FET switching configurations, more and more effect devices came to comprise this inexpensive method of switching. A most notable reason for maintaining and further developing electronic switching technology use was the dawning of digital effect devices.

Introduction of Digital Electronics to Effect Devices

Prior to the mid 1980's, essentially all guitar electronic effect devices comprised completely analog circuitry. Also, rarely was more than one type of effect device mounted in a single pedal, or enclosure. Such an attempt led to a very bulky, costly, and thus, typically unsuccessful product. With the evolution of technology, however, the mid-80's introduced the multiple effect device pedal, or “multi-effects” pedal. This multi-effects pedal could comprise a variety of effect device circuitry within a compact enclosure and could be equipped with a single set of control knobs or buttons by utilizing digitally programmed presets. In such a configuration, each effect device's settings were determined by presets established using the single set of knobs or buttons. The presets could be digitally stored by either the manufacturer or the user via memory means and could be recalled by the user via digital switching means. Thus, through the use of digital circuitry, a limited number of switches and control knobs or buttons could be provided on a pedal that comprised a plurality of different effect devices. Furthermore, such a pedal could be made compact in size through the development of surface mount technology (SMT) components, which were approximately equivalent in performance but extremely smaller than their standard-sized counterparts. Through the use of SMT, an entire multi-effects pedal could be provided within a compact enclosure with a single printed circuit board (PCB) comprising a plurality of effect device circuitry. Previously, an effect device required an enclosure just as big as the multi-effects pedal but contained typically only a single effect device circuit. Thus, SMT and digital electronics introduced a new category of guitar electronic effect devices.

While digitally-controlled multi-effects pedals could be made inexpensively and comprise a plurality of effect devices within a single enclosure and, additionally, comprise the added benefits of preset programming, such products were nevertheless scorned by many guitarists. Pure guitarists argued the True Bypass point, stating such products yielded a loss of the bypassed signal and further could not be bypassed upon loss of power. Other guitarists who were used to adjusting settings for various effect devices in real time complained that by utilizing a preset-style platform, making adjustments to settings on these pedals was aggravating and could not be done so quickly. Still others disliked the multi-effects pedals because, due to their digital nature, each of the many effect devices within the unit were scaled down versions of their older, single unit counterparts and thus, the user was limited to a finite number of digital settings. Additionally, many guitarists also disliked the complexity involved in operating such multi-effect pedals and dreaded the idea of having to spend a large amount of time to learn how to operate the equipment before they were able to use it. Thus, a large population of guitarists remained unsatisfied even with such apparent technological advancements in guitar electronic effect devices.

Return to Analog Electronics in Effect Devices

With the advent of the 1990's, however, this new breed of guitarists who demanded above all things, simple and high-quality products in all aspects relating to audio performance and operation, quickly began to receive attention. True Bypass became the buzz word and a feature demanded by guitarists of all levels. Using the term “digital” in a product description often resulted in complete rejection of the product by this “resurrection-of-all-analog” group of supporters. New “boutique” manufacturers quickly came about, many operating small businesses similar to the first effect device manufacturers of the 1960's and early 1970's. Products were hand-made and comprised only analog electronic components. Even analog SMT components, at this time commonly available, were practically always avoided by these manufacturers because they represented to the users characteristics of the scorned upon mass-produced digital effect devices. Not surprisingly, this growing market understood the performance benefits of DPDT True Bypass wiring, choosing the True Bypass DPDT configuration over the bypass with LED DPDT switching configuration. However, LED indication remained a desirable feature even if it did lose to True Bypass. Thus, it was a clear progression to employ a stomp switch comprising not just six poles as in a DPDT, but an extra set of three poles to allow for both True Bypass and LED indication. Such a switch, referred to as a triple-pole-double-throw (TPDT or 3PDT), existed already but had not been commonly manufactured in a stomp switch format. A 3PDT switch would be expensive to manufacture in a format durable, yet compact, enough for effect device enclosures. However, it appeared that the market was more than willing to pay extra for a product with such an advancement. One of the first and primary manufacturers, among this new group of boutique manufacturers, to employ 3PDT stomp switches in a completely analog and hand-made product was Fulltone™. Fulltone™, along with many other new boutique effect device manufacturers, gained success by manufacturing effect devices comprising “vintage” analog circuits dating back from the 1960's and 1970's but with improvements such as the new 3PDT True Bypass with LED indication switching arrangement and the use of higher quality components, namely components with lower tolerance values for improved consistency among overall production compared to the same vintage pedals they intended to recreate.

Realization of the Need for an Ideal Combination of Analog and Digital Electronics in Effect Devices

Despite these boutique manufacturers' success, guitarists in the beginning of the 21^{st} century intelligently now recognize that technology continues to improve. More and more of those guitarists who swore by the boutique manufacturers in the 1990's are curiously looking for products which can integrate digital technology with these analog effect devices, but do so in a way so as to maintain the desirable characteristics of analog pedals while gaining desired characteristics of digital electronics.

Clearly there exists a need for guitar electronic effect devices that comprise an even improved switching configuration which will provide True Bypass, LED indication of bypass status, performance without pops or other noises during switching, and that will be less expensive than other switching means. Furthermore, there exists a need for a product that comprises digital electronics for presetability but maintains the simplicity and greater flexibility of purely analog effect devices.

Survey of Prior Disclosures

While the prior art does disclose various switching and digital circuit elements, nowhere has their use been disclosed as a means to provide analog presets and improved true bypass analog switching. However, the following represent references to switching designs and circuit components that the inventor feels are the most relevant, and still, in any combination, do not approach the scope of the present invention.

In regards to analog switching, the following U.S. Patents comprise examples of field effect transistor (FET) switching techniques: Kikuchi et al. U.S. Pat. No. 3,942,039 entitled DISTORTIONLESS FET SWITCHING CIRCUIT, Albarran et al. U.S. Pat. No. 4,103,186 entitled LOW POWER JFET SWITCH, Ochi U.S. Pat. No. 4,138,614 entitled JFET SWITCH CIRCUIT, Sasayama et al. U.S. Pat. No. 4,604,535 entitled FET-BIPOLAR SWITCHING DEVICE AND CIRCUIT, Bowers et al. U.S. Pat. No. 5,055,723 entitled JFET ANALOG SWITCH WITH GATE CURRENT CONTROL, and Ham U.S. Pat. No. 6,114,897 entitled LOW DISTORTION COMPENSATED FIELD EFFECT TRANSISTOR (FET) SWITCH. Many of the FET switching techniques disclosed in this cited art may be utilized with guitar electronic effect devices wherein the FET switching circuit designs provide means for bypassing the effect device. Ideally, FET switching designs such as these provide inexpensive switching due to requiring as little as one momentary single-throw-single-pole (SPST) mechanical switch acting as a switching signal while FETs and other circuit components perform the overall bypass function. As previously discussed in the background of this application, however, FET switching has many drawbacks unacceptable for high performance guitar electronic effect devices such as signal loss due to the nature of non-True Bypass switching, creation of undesirable electrical switching noise, and loss of operation and ability to bypass without a power supply.

In regards to digital switching, the following U.S. Patents comprise switch debounce circuits useful for providing an accurate digital switching signal with a mechanical switch comprising imperfect switching characteristics: Hilliard, Jr. et al. U.S. Pat. No. 4,159,497 entitled SWITCH DEBOUNCE CIRCUIT, Norris et al. U.S. Pat. No. 4,523,104 entitled SWITCH DEBOUNCE CIRCUIT, and Floyd U.S. Pat. No. 4,549,094 entitled DEBOUNCE CIRCUIT PROVIDING SYNCHRONOUSLY CLOCKED DIGITAL SIGNALS. The circuits disclosed in these U.S. Patents may be coupled to any digital circuit component requiring an accurate digital switching signal to provide control means for the circuit component. In operation, these switch debounce circuits receive a switching signal from a mechanical switch which may be unstable, that is, the signal may bounce between connecting and disconnecting (or zero and one) very subtly before finally stabilizing at one position. These switch debounce circuits function to remove this signal instability and provide an output that is a pure digital switching signal free from any bouncing. Thus, these circuits enable a mechanical switch, such as a stomp switch described in the background of this application, to accurately control a digital circuit component. However, these switch debounce circuits clearly do not provide or suggest means of True Bypass switching or analog presets for a guitar electronic effect device.

In regards to digital counters, the following U.S. Patents represent circuit arrangements providing digital counter means: Roesler et al. U.S. Pat. No. 4,297,591 entitled ELECTRONIC COUNTER FOR ELECTRICAL DIGITAL PULSES and Yanagiuchi U.S. Pat. No. 5,896,428 entitled DIGITAL COUNTER AND DIGITAL PHASE LOCKED LOOP CIRCUIT USING SAME. The digital counters taught by these U.S. Patents provide a means for receiving a pulse digital input signal and providing a binary code output signal that increases with each additional pulse input and resets upon receiving a particular reset signal. By combining one of the digital counters disclosed in one of the above U.S. Patents with a switch debounce circuit previously discussed, a device can be constructed which utilizes a mechanical switch to provide an accurate pulse digital input signal for a counter circuit component which produces a binary code output signal, increasing upon each engagement of the switch. Importantly, however, any combination of a digital counter with a switch debounce circuit clearly does not provide or suggest means of True Bypass switching or analog presets for a guitar electronic effect device.

In regards to multiplexers for switching between different analog signals, the following U.S. Patents provide multiplexer arrangements suitable for analog signals: Esposito U.S. Pat. No. 4,498,166 entitled MULTIPLEXER AND DEMULTIPLEXER CIRCUITS FOR ANALOG SIGNALS and Allen et al. U.S. Pat. No. 5,801,571 entitled CURRENT MODE ANALOG SIGNAL MULTIPLEXOR. These U.S. patents disclose means for switching between various analog signals using a multiplexer arrangement controlled by an input signal, typically a digital input signal. Importantly, however, these U.S. patents do not teach or suggest means of providing True Bypass switching or analog presets for a guitar electronic effect device. Furthermore, even in combination with a switch debounce circuit and a digital counter, these multiplexer arrangements still do not provide or suggest means of True Bypass switching or analog presets for a guitar electronic effect device.

Thus, there exists a need for a guitar electronic effect device that utilizes a mechanical stomp switch and further comprises a True Bypass switching configuration, LED indication of bypass status, performance without pops or other noises during switching, and the desirable characteristic of being less expensive than other mechanical switching means. Furthermore, there exists a need for a product that utilizes digital circuit components to provide a means for analog presets, and that can be further coupled to the above-mentioned switching configuration to provide a guitar electronic effect device with said analog preset means and desired bypass switching characteristics.

### SUMMARY OF THE INVENTION

The present invention discloses an apparatus and method for providing analog, real-time settable presets for guitar electronic effect devices, or any other analog audio device, through the use of digital controls. This method for providing analog, real-time settable presets can be applied to any existing audio circuit for any type of audio control and any number of presets per control. Furthermore, the user is able to determine how many presets are desired per control by means of one or more easily accessible dual inline package (DIP) switches, or other readily available compact switches. An advantage of this switching system over other presetable devices is that all presets in the present invention are controlled and are made adjustable in real time. Thus, the present invention avoids the need to program presets at a time prior to use as well as eliminates the requirement for costly memory and microprocessor circuit components.

In one aspect of the present invention, a switch is coupled to a D flip-flop circuit component, an appropriate voltage supply, and resistance elements in order to generate a “debounced” signal commonly used in the art to provide a stable digital switching signal. This arrangement is used to provide a debounced digital bypass switching signal as well as one or more debounced digital counter control signals.

In a second aspect of the present invention, a triple two-to-one analog multiplexer is controlled by the digital bypass switching signal and provides True Bypass silent switching means between an input audio signal and an effected audio signal as well as LED indication of bypass status.

In a third aspect of the present invention, one or more digital counters are coupled to the one or more digital counter control signals to provide digital preset switching signals. In an additional aspect, DIP switches couple the digital preset switching signals to one or more NAND gates which are further coupled to the “reset” input bit of the digital counter. In this configuration, the DIP switches provide means for user control over the number of presets to be accessible via the preset switching signals.

In a fourth aspect of the present invention, one footswitch is used per each control that is to be presetable. A control in the form of a potentiometer of an existing analog audio circuit is replaced by a plurality of potentiometers or fixed resistors serving as presets. These plurality of resistance elements are coupled to an analog multiplexer which is further coupled to the audio circuit such that the multiplexer determines which one of the plurality of resistance elements is to be coupled to the audio circuit. The multiplexer receives a digital input switching signal for preset switching means. In a preferred embodiment, a dual-multiplexer may also be used in place of a single multiplexer, allowing light emitting diodes (LEDs) to be coupled to the opposite multiplexer of the dual-multiplexer in order to provide LED indication displaying which of the plurality of resistance elements is coupled to the audio circuit. Furthermore, other components or circuitry may be used in place of the resistance elements to provide a variety of different types of presettable controls.

Thus, it is an object of the present invention to provide a True Bypass, silent switching means between an audio input signal and an effected signal, wherein an LED is provided to indicate bypass status.

It is further an object of the present invention to provide preset switching signals which can easily be adjusted via DIP switch means to enable any number of different presets.

It is still a further object of the present invention to provide analog presets coupled to a multiplexer accepting preset switching means and a plurality of analog circuit components selectively coupled to an audio effect circuit, whereby the analog presets are controlled by simple user switching means.

### BRIEF DESCRIPTION OF THE DRAWINGS

A further understanding of the present invention can be obtained by reference to a preferred embodiment set forth in the illustrations of the accompanying drawings. Although the illustrated embodiment is merely exemplary of systems for carrying out the present invention, both the organization and method of operation of the invention, in general, together with further objectives and advantages thereof, may be more easily understood by reference to the drawings and the following description. The drawings are not intended to limit the scope of this invention, which is set forth with particularity in the claims as appended or as subsequently amended, but merely to clarify and exemplify the invention.

For a more complete understanding of the present invention, reference is now made to the following drawings in which:

FIG. 1 depicts a prior art SPDT bypass switching configuration.

FIG. 2 depicts a prior art DPDT bypass switching configuration with LED indication of bypass status.

FIG. 3 depicts a prior art DPDT True Bypass switching configuration.

FIG. 4 depicts a prior art 3PDT True Bypass switching configuration with LED indication of bypass status.

FIG. 5 depicts a DPDT True Bypass switching configuration of the present invention wherein switching noise is eliminated by grounding the circuit input during bypass mode.

FIG. 6 depicts an embodiment of the present invention comprising the switching configuration of FIG. 5 applied to a triple two-to-one analog multiplexer and further controlled by a common prior art switch debounce digital circuit comprising a momentary SPDT switch.

FIG. 7 depicts an embodiment of the present invention comprising a digital counter coupled to two user mode setting switches and a two-input NAND gate for reset means and further controlled by a common prior art switch debounce digital circuit.

FIG. 8 depicts an embodiment of the present invention comprising a digital counter coupled to three user mode setting switches and a three-input NAND gate for reset means and further controlled by a common prior art switch debounce circuit.

FIG. 9 depicts an analog preset switching system of the present invention comprising an analog multiplexer controlled by control bits provided by the embodiment of FIG. 7, presettable circuit elements each with a corresponding LED, and further coupled to a guitar electronic effect device circuit.

### DETAILED DESCRIPTION OF THE INVENTION

As required, a detailed illustrative embodiment of the present invention is disclosed herein. However, techniques, systems and operating structures in accordance with the present invention may be embodied in a wide variety of forms and modes, some of which may be quite different from those in the disclosed embodiment. Consequently, the specific structural and functional details disclosed herein are merely representative, yet in that regard, they are deemed to afford the best embodiment for purposes of disclosure and to provide a basis for the claims herein which define the scope of the present invention. The following presents a detailed description of a preferred embodiment (as well as alternative embodiments) of the present invention.

Bypass Switching Configurations

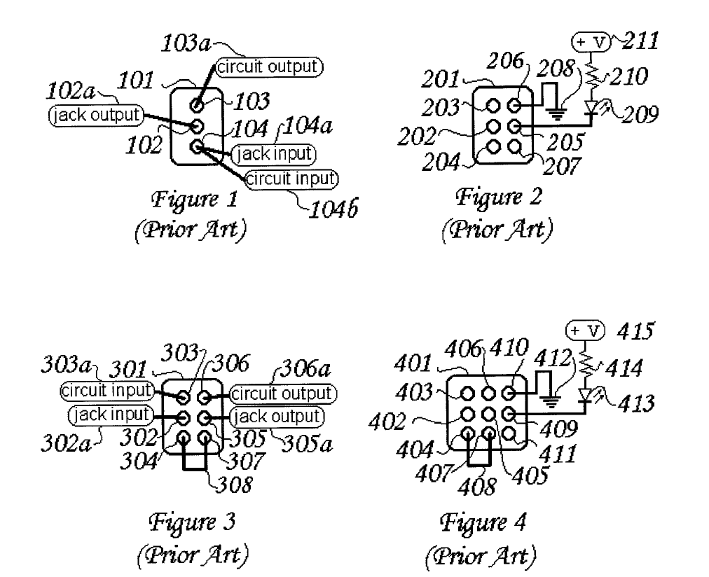

Referring first to FIG. 1, shown is a prior art SPDT bypass switch configuration for use with a guitar electronic effect device with a switch 101 comprising a middle pole 102 which electrically connects to a top pole 103 or a bottom pole 104, depending on the position of the switch 101. The middle pole 102 electrically connects to the output jack 102a of the device. The circuit output 103a of the device electrically connects to the top pole 103, and both the input jack 104a and the circuit input 104b of the device electrically connect to the bottom pole 104 of the switch 101. In such a configuration, the user can toggle between hearing the effected signal (i.e. circuit output 103a) or the original signal (i.e. from the input jack 104a) by engaging the switch 101. However, as noted in the background of this application, this SPDT switching configuration results in signal loss due to a continuous electrical connection of the input jack 104a and the circuit input 104b at the bottom pole 104. Furthermore, this SPDT switching configuration does not accommodate for LED indication of bypass status due to the limited number of poles 102-104, in this case only three.

The next logical progression for bypass switching in the art of guitar electronic effect device design was the implementation of the DPDT switch, which had twice the number of poles, functioning like a dual SPDT switch. Referring to FIG. 2, shown is a bypass method of prior art with a DPDT switch 201 comprising six poles 202-207. The first set of three poles 202-204 are equivalent and connected identical to the poles 102-104 in FIG. 1, whereupon a bypass switch is achieved making connections to an input jack, output jack, circuit input, and circuit output (not shown in FIG. 2 for clarity) as in the configuration of FIG. 1 with input jack 104a, output jack 102a, circuit input 104b, and circuit output 103a. The second set of three poles 205-207 switches in sequence with the first set of three poles 202-204. That is, when the first middle pole 202 is electrically connected to the first top pole 203, the second middle pole 205 is electrically connected to the second top pole 206. The second top pole 206 connects to a voltage source ground 208 and the second middle pole 205 connects to an LED 209 which is further connected to a positive voltage source 211 through a resistor 210. Thus, when the effected audio, or circuit output, (at pole 203) is coupled to the output jack (at pole 202) the LED 209 emits a light, indicating the device is on, and when the non-effected audio from the input jack (at pole 204) is electrically connected to the output jack (at pole 202) the LED 209 remains off, indicating the device is bypassed. While this DPDT switching arrangement allows LED indication of bypass status, this configuration still suffers from signal loss as stated in the description of FIG. 1 and is, therefore, undesirable.

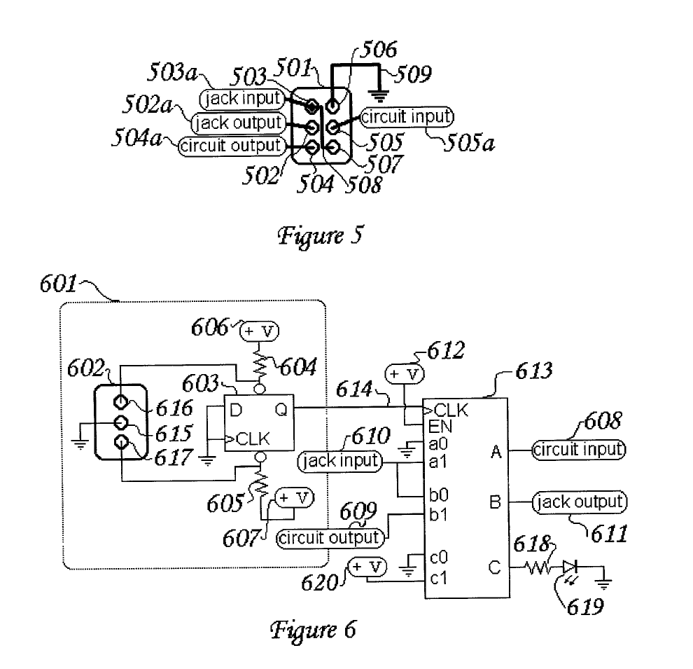

Referring next to FIG. 3, shown is an alternative DPDT switching configuration of prior art wherein True Bypass is provided without LED indication. The DPDT switch 301 comprises a first set of three poles 302-304 and a second set of three pole 305-307 which switch in sequence with one another. The wiring of FIG. 3, however, is much different from that of FIG. 2. In this embodiment, the input jack 302a and output jack 305a are electrically connected to the first and second middle poles 302 and 305, respectively. The circuit input 303a and circuit output 306a of the effect device are electrically connected to the first and second top poles 303 and 306, respectively. Finally, the first and second bottom poles, 304 and 307, are electrically connected to each other via a wire 308. In this configuration, the input signal at the input jack 302a is only connected to the circuit input 303a when the device is switched on, as opposed to the configuration of FIGS. 1 and 2 wherein the input jack 104a remains electrically connected to the circuit input 104b at all times. Thus, the configuration shown in FIG. 3 is not prone to signal loss in bypassed mode as are those of FIGS. 1 and 2. Nevertheless, the switching configuration of FIG. 3 is limited in that it does not provide LED indication of bypass status and, further, is prone to switching noise due to the connection and disconnection of the circuit input 303a from the input jack 302a during switching, which is discussed later in the description of FIG. 5.

FIG. 4 depicts another prior art advancement in bypass switching wherein a triple-pole-double-throw (TPDT or 3PDT) switch is used to provide both True Bypass and LED indication of bypass status. This configuration is essentially the direct combination of the first and second set of three poles 302-307 of FIG. 3 and the second set of three poles 205-207 of FIG. 2. Also, the circuit components 208-211 used in FIG. 2 are identical to those 412-415 of FIG. 4. By using nine poles 403-410 of the 3PDT switch 401 of FIG. 4 to replace the poles 302-307 and 205-207 of FIGS. 2 and 3, respectively, a single switch is able to perform True Bypass switching and LED indication of bypass status simultaneously. Despite the obvious advantage over other configurations, the switching arrangement of FIG. 3 still suffers from the switching noise mentioned in the description of the DPDT True Bypass of FIG. 3 and also is undesirable due to the expense of manufacturing and the larger size requirements.

FIG. 5 depicts an alternate bypass switching embodiment of the present invention comprising a DPDT switch 501 with a first set of three poles 502-504 and a second set of three poles 503-507. The first top pole 503 is electrically connected to the second bottom pole 507 via a wire 508. The second top pole 506 is electrically connected to a circuit ground connection 509. The input jack 503a electrically connects to the first top pole 503 while the output jack 502a electrically connects to the first middle pole 502. The effect device's circuit input 505a electrically connects to the second middle pole 505 while the effect device's circuit output 504a electrically connects to the first bottom pole 504. In this configuration, in the non-bypass position the switch 501 electrically connects the input jack 503a (at pole 507 through a wire 508) with the circuit input 505a (at pole 505) and the output jack 502a (at pole 502) with the circuit output 504a (at pole 504). In the bypass position, the switch 501 electrically connects the input jack 503a (at pole 503) with the output jack 502a (at pole 502) and the effect device's circuit input 505a (at pole 505) with the circuit ground 509 (at pole 506). In this novel arrangement, True Bypass is established and additionally, the circuit input is always electrically connected to a source—either the input jack 503a or the circuit ground 509. Thus, in bypass mode, the circuit input 505a of FIG. 5 is grounded while the circuit inputs of FIGS. 3 (303a) and 4 (at pole 403a, not shown) in bypass mode are not connected to any circuit element. In this configuration, the switching noise occurring from switching a circuit input from an input jack connection to no connection, and vice versa, found in switching designs of FIGS. 3 and 4 is eliminated in the new arrangement in FIG. 5. Additionally, a 3PDT switch can be used to combine the True Bypass switching design of FIG. 5 with LED indication of bypass similar to that of FIG. 4, wherein the first and second sets of three poles 402-407 of FIG. 4 are replaced by the poles 502-507 of FIG. 5.

FIG. 6 depicts an expansion of the bypass switching concept introduced in FIG. 5, wherein a triple two-to-one analog multiplexer 613, enclosed within a DIP (dual in-line package) or similar compact component package, replaces the bulky 3PDT switch used for True Bypass with LED indication switching configurations. The analog multiplexer 613 is controlled by a clock signal 614 which is generated by a debounced switching circuit 601 common in the art of digital electronics. The debounced switching circuit 601 may comprise a D flip-flop 603 as shown or may be configured with other digital logic components to achieve the same result. The switch 602 used to control the debounced switching circuit 601 is a momentary SPDT switch, wherein the middle pole 615 electrically connects to the top pole 616 but momentarily disconnects from the top pole 616 to momentarily connect to the bottom pole 617 upon engaging the switch 602. The effect device's circuit input 608 and circuit output 609 connections are coupled to the analog multiplexer 613 as shown, along with the effect device's jack input 610 and jack output 611 connections. The multiplexer 613 comprises three pairs of input pins a0-a1, b0-b1, and c0-c1 which correspond to output pins A, B, and C, respectively. Upon activating the circuits 601 and 613 by powering the voltage sources 606, 607, and 612, the first set of input pins a0, b0, and c0 are electrically connected to the output pins A, B, and C, respectively. When the user engages the switch 602 a first time, however, the second set of input pins a1, b1, and c1 are electrically connected to the output pins A, B, and C, respectively. Alternately, when the user engages the switch 602 again the output pins A, B, and C are switched to electrically connect to the first set of input pins a0, b0, and c0, respectively, again. The process of switching between the first and second set of input pins a0-a1, b0-b1, and c0-c1 continues with each additional engagement of the switch 602. The EN input pin is an enable bit wherein the multiplexer will only function when the EN pin receives a logic one signal. Thus, the EN pin is shown here connected to a positive supply voltage 612. Additionally, an LED 619 is connected to the C output pin of the multiplexer 613 through a resistor 618 to provide LED indication. Upon engaging the switch 602 to electrically connect the second set of input pins a1, b1, and c1 to the output pins A, B, and C, respectively, the resistor connects to ground and the LED 619 remains off. Alternately, upon engaging the switch 602 to electrically connect the first set of input pins a0, b0, and c0 to the output pins A, B, and C, respectively, the resistor 618 connects to a positive voltage supply 620 causing the LED 619 to turn on. Thus, when the input jack 610 electrically connects directly to the output jack 611 without connecting to circuit input and output connections 608-609, as in the case when the first set of input pins a0, b0, and c0 are connected to the output pins A, B, and C, respectively, the LED 619 is not lit as the effect device is bypassed. When the input jack 610 electrically connects to the device's circuit input 608 and the output jack 611 electrically connects to the device's circuit output 609, as in the case when the second set of input pins a1, b1, and c1 are connected to the output pins A, B, and C, respectively, however, the LED 619 is activated. In this embodiment of FIG. 6, the True Bypass switching of FIG. 5 is achieved but with additional LED indication of bypass status and with the replacement of the DPDT switch 501 with a momentary SPDT switch 602 used in a debounced switching circuit 601 with a conventional D flip-flop configuration. Thus, desirable True Bypass with LED indication switching is achieved with a smaller, less expensive SPDT switch 602 and two small circuit component packages comprising a D flip-flop 603 and an analog multiplexer 613.

While a preferred embodiment of the present invention's novel bypass switching means is shown in FIG. 6, alternate embodiments may also be utilized. For example a potentially less expensive combination of a dual two-to-one analog multiplexer and a single two-to-one digital multiplexer can be used to replace the triple two-to-one analog multiplexer 613 depicted. Additionally, as previously mentioned, a variety of switch debounce circuits can be used to replace the debounced switching circuit 601 used in FIG. 6. Furthermore, an analog input signal used with the present invention may first be converted to a digital signal, thus allowing the multiplexer 613 to be a less expensive digital multiplexer. The digital output signal provided at the output of the multiplexer may then be converted back to an analog signal approximately equivalent to the original input signal. Additionally, the components labeled jack input 610 and jack output 609 may comprise other circuit elements, circuit connection points, or connector means other than conventional jacks. Finally, the bypass configuration detailed in FIG. 6 may be applied not only to any guitar electronic effect device, but also to any other electronic device requiring a True Bypass with LED indication of bypass status switching configuration.

Digital Preset Switching Signals

In addition to providing novel bypass switching means previously described, it is another aspect of the present invention to provide digital counter means for the control of the analog preset means to be described later in this application. Furthermore, it is an aspect of the present invention to provide such digital counter means whereby the user can easily control via the combination of a momentary SPDT footswitch and one or more DIP switches or other compact switches.

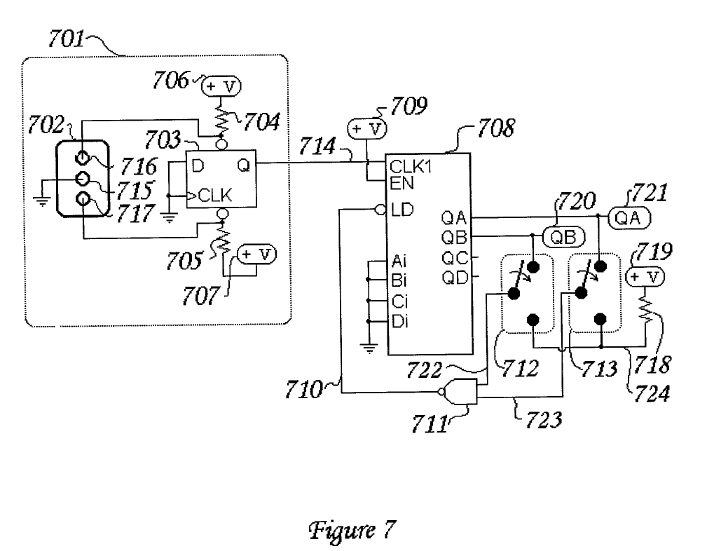

Referring now to FIG. 7, depicted is a four-bit digital counter 708 controlled by a clock signal 714 which is generated by a debounced switching circuit 701. As in the debounced switching circuit 601 of FIG. 6, the switching circuit 701 of FIG. 7 is controlled by a momentary SPDT switch 702. The EN pin of the counter 708 is connected to a positive voltage supply 709 in order for the counter 708 to operate. The initial bits Di-Ci-Bi-Ai are all grounded to yield an initial output of ‘0-0-0-0’ (the four-bit binary representation of zero) at the output bits QD-QC-QB-QA, respectively. In operation, the user engages the switch 702, which causes the debounced switching circuit 701 to generate a first pulse at the clock signal 714. This first pulse at the clock signal 714 is received at the CLK1 pin of the counter 708 and causes the counter 708 to produce an output of ‘0-0-0-1’ (the four-bit binary representation of one) at the output bits QD-QC-QB-QA, respectively. Upon the user engaging the switch 702 a second time, the process repeats with the output pins QD-QC-QB-QA now yielding ‘0-0-1-0’ (the four-bit binary representation of two). With each additional engagement of the switch 702, the four-bit binary representation of the output bits QD-QC-QB-QA increase by one. For example, the output bits QD-QC-QB-QA for the next three engagements of the switch 702 would be ‘0-0-1-1’ (the four-bit binary representation of three), ‘0-1-0-0’ (the four-bit binary representation of four), and ‘0-1-0-1’ (the four-bit binary representation of five). Thus, the four-bit digital counter 708 used in FIG. 7 will produce an output of bits representing from zero to fifteen for this 4-bit counter 708 (or from zero to 2ⁿ−1, for n-bits). Upon reaching the largest possible value, the counter 708 restarts with the initial value bits, ‘0-0-0-0’ in this case. Additionally, the counter 708 comprises a reset or load pin LD. Upon receiving a logic zero signal, this active low load pin LD will automatically reset the counter 708 to the initial value bits Di-Ci-Bi-Ai. This feature of the load pin LD is used in the present invention to provide user settable analog preset control bits (QB-QA) which will be described as follows.

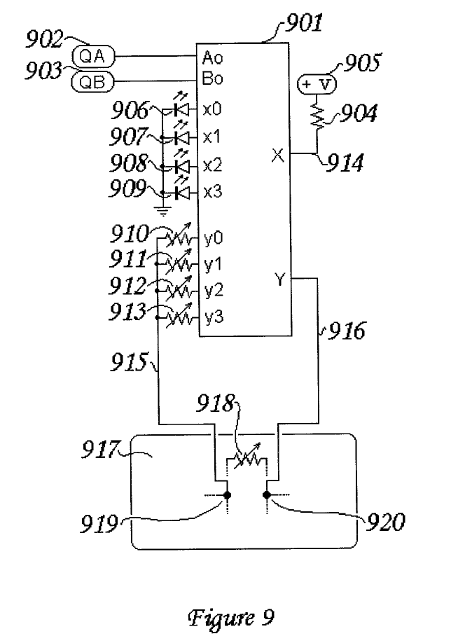

The two-input NAND gate 711 comprises the characteristic of only yielding a logic zero output 710 when both inputs 722-723 equal a logic one. Thus, the counter 708 will reset to the initial input bits, ‘0-0-0-0’ in this case, whenever the first and second NAND inputs 722-723 equal a logic one. Utilizing these characteristics, through the use of a first 712 and second 713 switch, the user is able to determine how many of the four states (zero through three) will be provided at control bits QB-QA. For example, by arranging the first switch 712 to electrically connect QB with the first NAND input 722 and arranging the second switch 713 to electrically connect QA with the second NAND input 722, the counter 708 does not reset until the control bits QB-QA equal the fourth stage (i.e., when QB-QA equals 1-1). In a second arrangement, if the user changes the second switch 713 to electrically connect to wire 724, which comprises a logic one from the positive voltage supply 719 which it is connected to through a resistor 718, the counter 708 resets when the control bits QB-QA equal the third stage. Similarly, in a third arrangement, if the user changes the first switch 712 to electrically connect to wire 724 comprising a logic one, while the second switch 713 is electrically connected to QA, the counter 708 resets when the control bits QB-QA equal the second stage. Thus, by utilizing the first and second switches 712-713 in the embodiment of FIG. 7, the user can easily determine how many of the four possible stages occurring in control bits QB-QA should be traversed by the counter. Since the control bits QB-QA will determine what analog preset will be chosen in FIG. 9 described later in this application, the two switches 712 and 713 give the user the ability to easily control the analog preset means of the present invention.

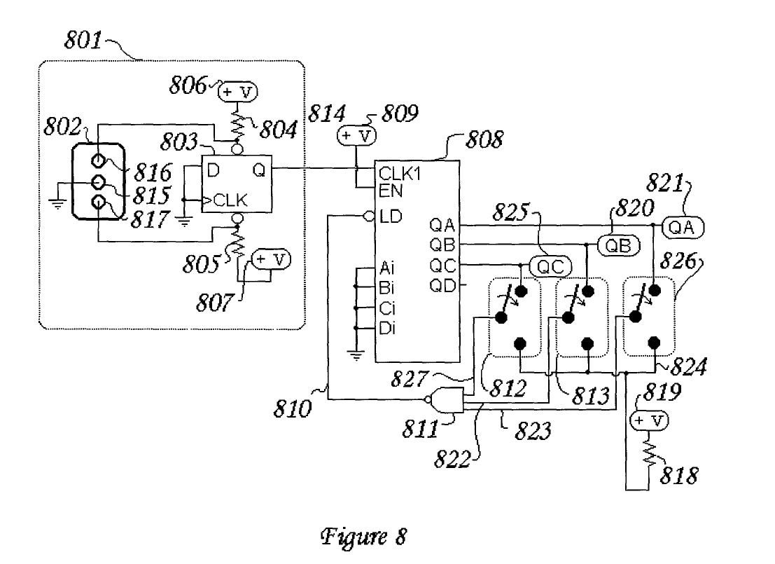

While FIG. 7 only utilizes two bits QB-QA of the 4-bit counter, and likewise uses two switches 712-713 to control the stage selection of these bits QB-QA, alternate embodiments may utilize additional bits with a corresponding number of additional switches to control a larger number of stages. For example, FIG. 8 depicts the same arrangement of FIG. 7 but with a three input NAND gate 811 replacing the two input NAND gate 711 of FIG. 7, an additional third switch 812 (with new first and second switches 813 and 826 replacing the first and second switches 712 and 713 of FIG. 7), and further utilizing output bit QC. In this configuration of FIG. 8, eight states are possible from control bits QC-QB-QA (states zero through seven). The three switches 812, 813, and 826 can be configured to allow the traversal of anywhere from all eight states to only between two states. (Note: a configuration can also be made to allow only one state, but this would defeat the purpose of having a mode switch to change between different modes. In effect, such a setting would disable to mode switch). For example, the following table indicates which of the three NAND gate inputs 822, 823, and 827 must be electrically connected to wire 824 (comprising a logic one signal) via corresponding switches 812, 813, and 826 to achieve the desired state traversal of control bits QC-QB-QA:

| | NAND gate inputs |
|---|---|
| State Traversals | connected to wire 824 |
| 1-2-3-4-5-6-7-8-(repeat) | none |
| 1-2-3-4-5-6-7-(repeat) | 823 |
| 1-2-3-4-5-6-(repeat) | 822 |
| 1-2-3-4-5-(repeat) | 823 and 822 |
| 1-2-3-4-(repeat) | 827 |
| 1-2-3-(repeat) | 827 and 823 |
| 1-2-(repeat) | 827 and 822 |
| 1 only | 827, 823, and 822 |

A common example of the four-bit counters 708 and 808 depicted in FIGS. 7 and 8, respectively, is the 74×169. Clearly, other counters comprising more or less bits may be used to provide more or less range in the output bits. With the embodiment of FIG. 7, only two bits, QB-QA are used for an output range of zero to three, or four total states. Alternately, the embodiment of FIG. 8 utilizes three bits, QC-QB-QA, for an output range of zero to seven, or eight total states. The number of bits used determines how many modes are possible for the analog preset embodiment described later in this application. For an n-bit counter, 2ⁿ modes are possible. Furthermore, to provide means for determining how many of the 2ⁿ states can be used in an n-bit counter, n-switches are required along with an n-input NAND (or equivalent digital circuit), as shown in the embodiments of FIGS. 7 and 8 which utilize two (712 and 713) and three (812, 813, and 826) switches as well as a two (711) and three (811) input NAND, respectively. Additionally, in place of a common NAND gate, any multiple digital input component performing a function of outputting a particular digital signal based upon the cumulative effect of all of the inputs may be applied to the circuit of, or similar to, FIGS. 7 and 8. Thus, a nearly infinite number of stages for preset means can be established by utilizing a larger and larger number of bit counter. For example, a ten-bit counter along with ten switches and an equivalent of a ten input NAND would provide 2¹⁰, or 1024, possible states and the ability to decide exactly how many of these states can be traversed before the counter resets.

Analog Preset Switching System

It is another aspect of the present invention to utilize the digital preset switching, or control, signals QB-QA of FIG. 7 and QC-QB-QA of FIG. 8—as well as switching signals of alternate embodiments to those of FIGS. 7 and 8 comprising more bits—to provide analog preset means for a complete analog preset switching system. Referring now to FIG. 9, depicted is a two-bit dual four-to-one analog multiplexer 901 which receives control signals QB-QA 903 and 902, respectively, from a two-bit digital preset switching system such as the one detailed in FIG. 7. The control signals 903 and 902 determine which of the four input pins x0-x1-x2-x3, will be connected to output pin X and, similarly, which of the four input pins y0-y1-y2-y3 will be connected to output pin Y. A guitar electronic effect device circuit 917 (the details of the effect device circuit 917 are not shown for simplicity) is coupled to the analog multiplexer 901 through a first wire 915 and a second wire 916. An example of a guitar electronic effect device circuit 917 that may be used in this configuration may be a tremolo circuit wherein a variable resistor in the form of a potentiometer 918 can be adjusted by the user to determine the speed of the tremolo effect. Any other guitar electronic device, for example, a chorus, phaser, flanger, delay, octavia, pitch shifter, equalizer, compressor, wah, envelope-controlled filter follower, distortion, overdrive, and a growing number of other sound altering devices, may also be used as the effect device circuit 917. Nodes 919 and 920 show where the potentiometer 918 would connect to the rest of the circuit 917 (again, the rest of the tremolo effect circuit 917 is not shown for simplicity). With the present invention, however, the potentiometer 918 on the effect device circuit 917 is replaced by the first wire 915 and the second wire 916 which couple the effect device circuit 917 to the analog multiplexer 901 at nodes 919 and 920, respectively. In such a configuration, a selected one of the resistors 910-913—all coupled on one side to the first wire 915, further connected to node 919 of the effect device circuit 917, and on the other side to one of the input pins y0-y3, respectively—replaces the potentiometer 918 originally in the effect device circuit 917. In operation, the control bits 903 and 902 determine which one of the resistors 910-913 is connected to the second wire 916 which is further connected to the effect device circuit 917 at node 920 where the potentiometer 918 previously was in place. Thus, the control bits 903 and 902 determine which one of the resistors 910-913 will replace the original potentiometer 918 in the effect device circuit 917. Additionally, the dual four-to-one analog multiplexer 901 comprises a second half wherein one of the LEDs 906-909 is activated in accordance with which one of the resistors 910-913 is connected to the effect device circuit 917. Thus, the user is provided with LED indication of which resistor 910-913 is utilized in the effect device circuit 917.

Alternate embodiments to FIG. 9 may exist wherein the analog multiplexer 901 may comprise a fewer or greater number of bits and, thus, the corresponding system would comprise a corresponding fewer or greater number of analog presets. For example, an eight-input multiplexer may be used with the digital preset switching signal embodiment of FIG. 8 comprising three control bits QC-QB-QA. Similarly, any 2ⁿ-input multiplexer may be used with a digital preset switching signal embodiment comprising n control bits. Furthermore, in place of a dual analog multiplexer 901, a single analog multiplexer may be coupled to the resistors 910-913 while a single digital multiplexer may be coupled to the LEDs 906-909, with each single multiplexer receiving the same control bits 903 and 902. Such an arrangement with two single multiplexers, one analog and one digital, may prove less expensive than a dual analog multiplexer.

In a preferred embodiment of the present invention, the resistors 910-913 are potentiometers with control knobs mounted externally on a guitar electronic effect device. The user is then able to make preferred settings using the control knobs. Additionally, a switch, in the form of a momentary SPDT stompswitch, controls a digital preset switching circuit like that of FIG. 7 which provides control bits 903 and 902. This switch, herein referred to as the “analog preset switch”, determines which one of the presets provided by a respective resistor 910-913 is enabled In operation, upon powering the device the first preset provided by the first resistor 910 is coupled to nodes 919 and 920 of the effect device circuit 917 and the first LED 906 is turned on. Upon engaging the analog preset switch a first time the analog multiplexer 901 switches from the first preset to the second preset provided by the second resistor 911 which is now coupled to the nodes 919 and 920 and the second LED 907 is now turned on as the first LED 906 turns off. Similarly, upon engaging the analog preset switch a second time the third preset, comprising the third resistor 912, is enabled as the third LED 908 is the only turned on LED connected to the multiplexer 901. Finally, upon engaging the analog preset switch a third time the fourth preset, comprising the fourth resistor 913 and the fourth LED 909, is enabled while the other resistors 910-912 and LEDs 906-908 remain disconnected from output pins Y and X, respectively.

Recalling FIG. 7, the first and second switches 712 and 713 can now be used to determine how many of the analog presets (provided by the resistors 910-913 and the LEDs 906-909) can be recalled using the analog preset switch. For example, the following table indicates which of the NAND gate inputs 722 and 723 are to be electrically connected to wire 724 (comprising a logic one signal) via corresponding switches 712 and 713 to achieve the desired traversal of analog presets, whereupon each additional engagement of the analog preset switch the next analog preset in the Analog Preset Traversals list (from left to right) is enabled:

| Analog Preset | NAND inputs |
|---|---|
| Traversals | connected to wire 724 |
| 1-2-3-4-(repeat) | none |
| 1-2-3-(repeat) | 723 |
| 1-2-(repeat) | 722 |
| 1-only | 723 and 722 |

Thus, utilizing two switches 712-713 in a digital preset switching circuit like that of FIG. 7, the user can simply choose which of the plurality of analog presets can be accessed via an analog preset switch.

The preferred embodiment of the present includes a True Bypass switching circuit like that of FIG. 6, a digital preset switching circuit like that of FIG. 7, and an analog preset multiplexer circuit like that of FIG. 9 coupled to a guitar electronic effect device circuit 917. The circuit element replaced in FIG. 9, the potentiometer 918, for one of a plurality of other similar circuit elements, resistors 910-913, may also be any other type of circuit component such as a capacitor, inductor, diode, transistor, one or more pins of an integrated circuit, a voltage regulator, or any small or large circuit wherein one or more nodes of the circuit are connected to one of a plurality of possible other nodes of other circuits via a multiplexer or other switching means. Furthermore, the embodiment comprising FIGS. 6, 7, and 9 may be modified to include a fewer or greater number of analog presets, which would in turn require a fewer or greater number of control bits (n control bits corresponding to up to 2ⁿ analog presets). Similarly, n number of switches for preset traversal setting means can be used with a multiplexer comprising n-bits to allow the user to set the number of analog presets that will be accessed in a complete transversal of all accessible analog presets via engaging the analog preset switch. Additionally, more than one effect device control may be presettable wherein a separate analog preset circuit (e.g., FIG. 7 or 8), digital preset switching circuit (e.g., FIG. 6), analog preset switch, and preset traversal setting means (e.g., switches 712 and 713 in FIG. 7) is provided for each of the effect device controls to be presettable. Examples of other presettable controls may include volume/output, intensity of effect, mix of wet/dry signals, tone (e.g., treble, bass, mid-range), other equalizer settings, and any other level-based or switch-based feature on a guitar electronic effect device.

The present invention may be manufactured to comprise all aspects of the invention combined with any guitar electronic effect device circuit housed within a single enclosure. Furthermore, more than one set of the elements of the present invention may be housed within a single enclosure wherein this enclosure comprises analog presetting means for more than one effect device circuit and/or for more than one control of said one or more effect device circuits. Alternately, the present invention may be manufactured with all aspects of the invention housed in an enclosure separate from that of the effect device circuit of which the invention is to be coupled to. The coupling means of the present invention with an effect device circuit may comprise one or more cords and/or jacks, or may comprise any other corded or wireless coupling means. Additionally, the present invention may be configured such that it can be easily coupled to an existing guitar electronic effect device without implementing complex or potentially damaging procedures on either the present invention or the existing effect device.

In one embodiment, the present invention is constructed on a removable printed circuit card or other removable device, wherein the effect device to be coupled to the invention is further equipped with a slot or other connection means. In another embodiment, the present invention may be constructed on a printed circuit card or other device wherein this card has solder tabs or other connection means for more permanently coupling the invention with an effect device. In such an embodiment the printed circuit card may be soldered to wires which are further coupled to the effect device or the printed circuit card may comprise some form of connector means, either permanent or removable, to connect to an element which couples the invention to the effect device.

The present invention may also be coupled to non-guitar electronic effect devices. That is, any device comprising a control element can be coupled to the preset and/or bypass system of the present invention for easy preset controls and/or bypass switching without requiring memory and microprocessor means. The device may comprise any audio circuit as well as any digital circuit that may benefit from such a user-friendly preset system. Furthermore, the present invention may also include digital memory means which may be used to store presets for use with the circuit elements used by the present invention. Microprocessors and other digital means may also be included for additional preset storage, recall, and control means.

While the present invention has been described with reference to one or more preferred embodiments, such embodiments are merely exemplary and are not intended to be limiting or represent an exhaustive enumeration of all aspects of the invention. The scope of the invention, therefore, shall be defined solely by the following claims. Further, it will be apparent to those of skill in the art that numerous changes may be made in such details without departing from the spirit and the principles of the invention.

I claim:

1. A switching apparatus, said switching apparatus comprising at least two sets of at least three poles and control means, said control means allowing a user to electrically couple at least one pole of each of said at least two sets of at least three poles to at least one other pole of said each of said at least two sets of at least three poles, said switching apparatus coupled to at least two input connections and at least two output connections wherein at least one of said at least two input and output connections are coupled to a circuit comprising a voltage supply and a circuit ground, wherein:
a first pole is electrically coupled to either a second pole or a third pole in a first set of said at least two sets of at least three poles in accordance with said control means;
a first pole is electrically coupled to either a second pole or a third pole in a second set of said at least two sets of at least three poles in accordance with said control means and in unison with said first set of said at least two sets of at least three poles;
said second pole of said first set of said at least two sets of at least three poles is electrically coupled to said third pole of said second set of said at least two sets of at least three poles;
said second pole of said second set of said at least two sets of at least three poles is electrically coupled to said circuit ground;
said second pole of said first set of said at least two sets of at least three poles is electrically coupled to a first of said at least two input connections;
said first pole of said second set of said at least two sets of at least three poles is electrically coupled to a second of said at least two input connections;
said first pole of said first set of said at least two sets of at least three poles is electrically coupled to a first of said at least two output connections; and
said third pole of said first set of said at least two sets of at least three poles is electrically coupled to a second of said at least two output connections.

2. A switching apparatus according to claim 1 wherein said switching apparatus further comprises LED indication means, said LED indication means comprising:
at least one light emitting diode comprising a first and second end, said light emitting diode coupled on said first end to a first pole of a third set of said at least two sets of three poles and on said second end to a resistor, said resistor further coupled to said voltage supply and
a second pole of said third set of at least two sets of three poles, said second pole of said third set of at least two sets of three poles coupled to said circuit ground.

3. A switching apparatus according to claim 1 wherein said control means comprises:
a switch controlled by a user to generate a switching signal;
a switch debounce circuit coupled to said switching signal to generate a clock signal; and
a multiplexer, said multiplexer controlled by said clock signal, said multiplexer coupled to said at least two sets of at least three poles and said at least two input connections and at least two output connections.

4. A switching apparatus according to claim 1 wherein said control means comprises:
a switch controlled by a user to generate a switching signal;
a switch debounce circuit coupled to said switching signal to generate a clock signal;
LED indication means, said LED indication means comprising at least one light emitting diode comprising a first and second end, said light emitting diode coupled on said first end to a first pole of a third set of said at least two sets of three poles and on said second end to a resistor, said resistor further coupled to said voltage supply, and said LED indication means further comprising a second pole of said third set of at least two sets of three poles, said second pole of said third set of at least two sets of three poles coupled to said circuit ground; and
a multiplexer, said multiplexer controlled by said clock signal, said multiplexer coupled to said at least two sets of at least three poles, said at least two input connections and at least two output connections, and said LED indication means.

5. An analog preset switching system, said analog preset switching system comprising:
switching means for electrically coupling one or more output pins of one or more sets of pins to a selected one or more of a plurality of input pins of the same set of said one or more sets of pins;
coupling means for coupling said switching means to an electronic circuit;
control means for controlling said switching means;
preset means, said preset means coupling a plurality of circuit elements, said plurality of circuit elements coupled to one or more of said plurality of input pins.

6. An analog preset switching system according to claim 5 wherein said analog preset switching system comprises a bypass switching apparatus, said bypass switching apparatus comprising at least two sets of at least three poles and control means, said control means allowing a user to electrically couple at least one pole of each of said at least two sets of at least three poles to at least one other pole of said each of said at least two sets of at least three poles, said switching apparatus coupled to at least two input connections and at least two output connections wherein at least one of said at least two input and output connections are coupled to a circuit comprising a voltage supply and a circuit ground, wherein:
a first pole is electrically coupled to either a second pole or a third pole in a first set of said at least two sets of at least three poles in accordance with said control means;
a first pole is electrically coupled to either a second pole or a third pole in a second set of said at least two sets of at least three poles in accordance with said control means and in unison with said first set of said at least two sets of at least three poles;
said second pole of said first set of said at least two sets of at least three poles is electrically coupled to said third pole of said second set of said at least two sets of at least three poles;
said second pole of said second set of said at least two sets of at least three poles is electrically coupled to said circuit ground;
said second pole of said first set of said at least two sets of at least three poles is electrically coupled to a first of said at least two input connections;
said first pole of said second set of said at least two sets of at least three poles is electrically coupled to a second of said at least two input connections;
said first pole of said first set of said at least two sets of at least three poles is electrically coupled to a first of said at least two output connections; and
said third pole of said first set of said at least two sets of at least three poles is electrically coupled to a second of said at least two output connections.

7. An analog preset switching system according to claim 5 wherein said switching means comprises a multiplexer.

8. An analog preset switching system according to claim 5 wherein said control means comprises a digital counter.

9. An analog preset switching system according to claim 5 wherein said switching means comprises:
a switch controlled by a user to generate a switching signal;
a switch debounce circuit coupled to said switching signal to generate a clock signal; and
a multiplexer, said multiplexer controlled by said clock signal, said multiplexer electrically coupling said one or more output pins of said one or more sets of pins to said selected one or more of said plurality of input pins of the same set of said one or more sets of pins;

10. An analog preset switching system according to claim 5 wherein said control means comprises:
a switch controlled by a user to generate a switching signal;
a switch debounce circuit coupled to said switching signal to generate a clock signal; and
a digital counter controlled by said clock signal, said digital counter providing a switching control signal, said switching control signal coupled to said switching means.

11. An analog preset switching system according to claim 5 wherein said control means comprises:
a switch controlled by a user to generate a switching signal;
a switch debounce circuit coupled to said switching signal to generate a clock signal; and
a digital counter controlled by said clock signal, said digital counter providing a switching control signal, said switching control signal comprising one or more digital bits, said one or more digital bits coupled to said switching means; and
wherein said analog preset switching system further comprises switching control signal preset means, said switching control signal preset means comprising:
at least one bit control switch, said at least one bit control switch selectively electrically coupling either said voltage supply or one of said one or more digital bits to an input of a multiple input digital component, said multiple input digital component performing a function of outputting a particular digital signal based upon the cumulative effect of all of the inputs.

12. An analog preset switching system according to claim 5 wherein said electronic circuit comprises one or more controls, said one or more controls coupled to one or more electrical modes of said electronic circuit, said electrical nodes coupled to said switching means.

13. An analog preset switching system according to claim 5 wherein said switching means utilize a combination of one or more analog multiplexers and one or more digital multiplexers.

14. An analog preset switching system according to claim 5 wherein said electronic circuit is provided within a first device external from a second device, said second device comprising said switching means.

15. An analog preset switching system according to claim 5 wherein said electronic circuit and said switching system are provided within a single enclosure.

16. An analog preset switching system according to claim 5 wherein said switching means is provided on a matter, said matter removably coupled to said electronic circuit.

17. An analog preset switching system according to claim 5 wherein said switching means are enclosed within a footpedal.

18. An analog preset switching system according to claim 5 wherein said analog preset switching system further comprises a remote unit, said remote unit comprising said preset means.

19. An analog preset switching system according to claim 5 wherein said analog preset switching system further comprises digital memory means, said digital memory means digitally storing presets for use with said circuit elements.

20. A method for providing an analog preset switching system comprising the steps of:
a) setting a plurality of analog controls;
b) setting one or more enabling switches to enable a selected number of said plurality of analog controls;
c) coupling an electronic circuit to a first of said plurality of analog controls;
d) engaging a mode switch and coupling said electronic circuit to a second of said plurality of analog controls and disconnecting said first of said plurality of analog controls; and
e) coupling said electronic circuit to another of said plurality of analog controls per each additional engagement of said mode switch and in accordance with said enabling switches;
whereupon reaching the maximum number of said selected number of enabled said plurality of analog controls, coupling said electronic circuit to said first of said plurality of analog controls and repeating the process with each additional series of engaging said mode switch.
